(19) United States
(12) Patent Application Publication
(10) Pub. No.: US 2023/0284365 A1
(43) Pub. Date: Sep. 7, 2023

(54) EXTREME ULTRAVIOLET LIGHT GENERATION SYSTEM AND ELECTRONIC DEVICE MANUFACTURING METHOD

(71) Applicant: Gigaphoton Inc., Tochigi (JP)

(72) Inventors: Yuichi NISHIMURA, Oyama-shi (JP); Shogo KITASAKA, Oyama-shi (JP)

(73) Assignee: Gigaphoton Inc., Tochigi (JP)

(21) Appl. No.: 18/165,063

(22) Filed: Feb. 6, 2023

(30) Foreign Application Priority Data
Mar. 7, 2022 (JP) 2022-034740
Aug. 12, 2022 (JP) 2022-128586

(51) Int. Cl. H05G 2/00; G03F 7/20

(52) U.S. Cl. CPC H05G 2/006; H05G 2/008; G03F 7/70033

(57) ABSTRACT

An extreme ultraviolet light generation system configured to generate extreme ultraviolet light by irradiating a target substance with laser light includes a nozzle configured to output the target substance, a vibration element that is driven by an input of an electric signal of a rectangular wave and applies vibration to the target substance to be output from the nozzle to generate droplets of the target substance, a first sensor configured to detect energy of the generated extreme ultraviolet light, a second sensor configured to detect energy of the laser light to be radiated to the target substance, and a processor configured to control a duty value of the electric signal for vibrating the vibration element so as to reduce a variation of an energy conversion efficiency calculated based on an output of the first sensor and an output of the second sensor.

The present application claims the benefit of Japanese Patent Application No. 2022-034740, filed on Mar. 7, 2022, and Japanese Patent Application No. 2022-128586, filed on Aug. 12, 2022, the entire contents of which are hereby incorporated by reference.

### BACKGROUND

### 1. Technical Field

The present disclosure relates to an extreme ultraviolet light generation system and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, the development of an exposure apparatus that combines an extreme ultraviolet (EUV) light generation apparatus that generates EUV light having a wavelength of about 13 nm and reduced projection reflection optics is expected. As the EUV light generation apparatus, a laser produced plasma (LPP) type apparatus using plasma generated by irradiating a target substance with laser light has been developed.

### LIST OF DOCUMENTS

### Patent Documents

Patent Document 1: U.S. patent Ser. No. 10/225,917
Patent Document 2: U.S. Pat. No. 9,000,403

### SUMMARY

An extreme ultraviolet light generation system, according to an aspect of the present disclosure, configured to generate extreme ultraviolet light by irradiating a target substance with laser light includes a nozzle configured to output the target substance, a vibration element that is driven by an input of an electric signal of a rectangular wave and applies vibration to the target substance to be output from the nozzle to generate droplets of the target substance, a first sensor configured to detect energy of the generated extreme ultraviolet light, a second sensor configured to detect energy of the laser light to be radiated to the target substance, and a processor configured to control a duty value of the electric signal for vibrating the vibration element so as to reduce a variation of an energy conversion efficiency calculated based on an output of the first sensor and an output of the second sensor.

An electronic device manufacturing method according to another aspect of the present disclosure includes generating extreme ultraviolet light using an extreme ultraviolet light generation system, outputting the extreme ultraviolet light to an exposure apparatus, and exposing a photosensitive substrate to the extreme ultraviolet light in the exposure apparatus to manufacture an electronic device. Here, the extreme ultraviolet light generation system includes a nozzle configured to output a target substance, a vibration element that is driven by an input of an electric signal of a rectangular wave and applies vibration to the target substance to be output from the nozzle to generate droplets of the target substance, a first sensor configured to detect energy of the extreme ultraviolet light generated by irradiating the target substance with laser light, a second sensor configured to detect energy of the laser light to be radiated to the target substance, and a processor configured to control a duty value of the electric signal for vibrating the vibration element so as to reduce a variation in energy conversion efficiency calculated based on an output of the first sensor and an output of the second sensor.

An electronic device manufacturing method according to another aspect of the present disclosure includes generating extreme ultraviolet light using an extreme ultraviolet light generation system, inspecting a defect of a reticle by irradiating the reticle with the extreme ultraviolet light, selecting a reticle using a result of the inspection, and exposing and transferring a pattern formed on the selected reticle onto a photosensitive substrate. Here, the extreme ultraviolet light generation system includes a nozzle configured to output a target substance, a vibration element that is driven by an input of an electric signal of a rectangular wave and applies vibration to the target substance to be output from the nozzle to generate droplets of the target substance, a first sensor configured to detect energy of the extreme ultraviolet light generated by irradiating the target substance with laser light, a second sensor configured to detect energy of the laser light to be radiated to the target substance, and a processor configured to control a duty value of the electric signal for vibrating the vibration element so as to reduce a variation of an energy conversion efficiency calculated based on an output of the first sensor and an output of the second sensor.

### BRIEF DESCRIPTION OF THE DRAWINGS

Embodiments of the present disclosure will be described below merely as examples with reference to the accompanying drawings.

FIG. 1 schematically shows the configuration of an EUV light generation system according to a comparative example.

FIG. 2 is a flowchart showing operation of the EUV light generation system according to the comparative example.

FIG. 3 schematically shows the configuration of the EUV light generation system according to a first embodiment.

FIG. 4 is a flowchart showing operation of the EUV light generation system according to the first embodiment.

FIG. 5 is a flowchart showing an example of a subroutine applied to step S13 in FIGS. 2 and 4.

FIG. 6 is a graph showing an example of an abnormal value occurrence rate of a droplet generation time interval measured in droplet combining adjustment.

FIG. 7 is a flowchart showing an example of a subroutine applied to step S16 in FIG. 4.

FIG. 8 is an explanatory diagram of a process of checking a gradient and changing a duty value to improve the index value.

FIG. 9 is an explanatory diagram showing an example of a process of an additional search performed when an absolute value of the gradient is larger than a threshold.

FIG. 10 is a graph showing an example of an energy conversion efficiency (CE) measurement value, a CE difference, and a frequency distribution of the CE difference in a case that the combining failure of the droplets is occurring.

FIG. 11 is a graph showing an example of the CE measurement value, the CE difference, and the frequency distribution of the CE difference in a case that the combining of the droplets is normal.

FIG. 12 is a flowchart showing an example of operation of the EUV light generation system according to the second embodiment.

FIG. 13 schematically shows the configuration of an EUV light generation system according to a third embodiment.

FIG. 14 is an explanatory diagram schematically showing a state of EUV light generation by a secondary target.

FIG. 15 schematically shows the configuration of an exposure apparatus connected to the EUV light generation system.

FIG. 16 schematically shows the configuration of an inspection apparatus connected to the EUV light generation system.

### DESCRIPTION OF EMBODIMENTS

### <Contents>

1. Description of terms
2. Outline of EUV light generation system according to comparative example
   2.1 Configuration
   2.2 Operation
   2.3 Problem
3. First Embodiment
   3.1 Configuration
   3.2 Operation
   3.3 Example of droplet combining adjustment
   3.4 Example of droplet combining control based on EUV light
   3.5 Example of evaluation method of CE
   3.6 Effect
4. Second Embodiment
   4.1 Configuration
   4.2 Operation
   4.3 Effect
5. Third Embodiment
   5.1 Configuration
   5.2 Operation
   5.3 Effect
6. Electronic device manufacturing method
7. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numerals, and duplicate description thereof is omitted.

### 1. DESCRIPTION OF TERMS

A “target” is an object to be irradiated with laser light introduced into a chamber. The target irradiated with the laser light is turned into plasma and emits light including EUV light.

A “droplet” is a form of a target supplied into the chamber. The droplet may refer to a droplet-shaped target having a substantially spherical shape due to surface tension of a molten target substance. In the present specification and drawings, the expression “DL” is an abbreviation of a “droplet.”

A “plasma generation region” is a predetermined region in the chamber. The plasma generation region is a region in which a target output into the chamber is irradiated with the laser light and in which the target is turned into plasma.

A “target trajectory” is a path along which a target output into the chamber travels. The target trajectory includes a travel axis of the target. The target trajectory intersects, in the plasma generation region, with an optical path of the laser light introduced into the chamber. The optical path includes an optical path axis.

An “optical path axis” is an axis passing through the center of a beam cross section of the laser light along a travel direction of the laser light.

The expression “EUV light” is an abbreviation for “extreme ultraviolet light.” An “extreme ultraviolet light generation system” is referred to as an “EUV light generation system.”

A “piezoelectric element” is synonymous with a piezoelectric device. The piezoelectric element may simply be referred to as a “piezo.” The piezoelectric element is an example of a vibration element that applies vibration to a target substance to generate droplets.

“Duty” refers to the ratio of a high-potential-side voltage time occupied in one pulse period in an electric signal of a rectangular wave. In the present specification, it refers to the duty of a driving voltage waveform applied to the piezoelectric element. In the present specification, the duty is expressed by percentage [%].

### 2. OUTLINE OF EUV LIGHT GENERATION SYSTEM ACCORDING TO COMPARATIVE EXAMPLE

### 2.1 Configuration

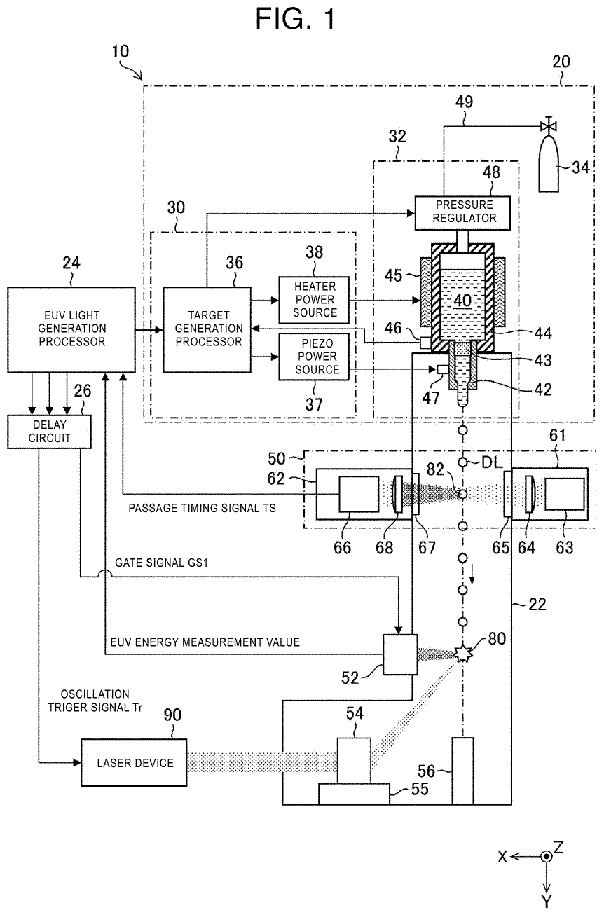

FIG. 1 schematically shows the configuration of an EUV light generation system 10 according to a comparative example. The comparative example of the present disclosure is an example recognized by the applicant as known only by the applicant, and is not a publicly known example admitted by the applicant.

The EUV light generation system 10 includes a target generation system 20, a chamber 22, an EUV light generation processor 24, a delay circuit 26, and a laser device 90. The target generation system 20 includes a target control system 30, a target supply unit 32, and an inert gas supply unit 34. The target control system 30 includes a target generation processor 36, a piezoelectric power source 37, and a heater power source 38. The processor in the present disclosure is a processing device including a storage device in which a control program is stored and a central processing unit (CPU) that executes the control program. The processor is specifically configured or programmed to perform various processes included in the present disclosure.

The target supply unit 32 includes a nozzle 42 including a hole for outputting a molten target substance 40, a filter 43 arranged upstream of the nozzle 42, a tank 44 for storing the target substance 40, a heater 45, a temperature sensor 46, a piezoelectric element 47, and a pressure regulator 48. The filter 43 removes impurities contained in the target substance 40. The target substance 40 is, for example, tin (Sn).

The nozzle 42, the heater 45, and the temperature sensor 46 are fixed to the tank 44. The piezoelectric element 47 is fixed to the nozzle 42.

The pressure regulator 48 is arranged at a pipe 49 between the inert gas supply unit 34 and the tank 44. An inert gas supplied from the inert gas supply unit 34 may be, for example, Ar or He gas.

The chamber 22 includes a droplet detection device 50, an EUV energy sensor 52, a laser light concentrating optical system 54, an XY-axis stage 55, a target collection unit 56, and an EUV light concentrating mirror (not shown).

The droplet detection device 50 includes a light source unit 61 and a light receiving unit 62. The light source unit 61 includes a CW laser 63 which is a light source, an illumination optical system 64 which is a light concentrating lens, and a window 65. The light source unit 61 is arranged so as to illuminate a droplet 82 at a predetermined position P on a target trajectory between the nozzle 42 of the target supply unit 32 and the plasma generation region 80.

The light receiving unit 62 includes an optical sensor 66 which is a light receiving element, and a window 67 and a light receiving optical system 68 for introducing CW laser light to the optical sensor 66. The light receiving unit 62 is arranged so as to receive CW laser light output from the light source unit 61. When the droplet 82 blocks the CW laser light, the output of the optical sensor 66 varies. The light receiving unit 62 generates a passage timing signal TS to notify the timing at which the droplet 82 passes through the position P based on the variation, and inputs the passage timing signal TS to the EUV light generation processor 24.

The EUV light generation processor 24 calculates a delay time based on the passage timing signal TS and sets the delay time in the delay circuit. The delay time has a fixed value. The delay circuit 26 may be configured as a part of the EUV light generation processor 24.

A signal line for setting the delay time of the delay circuit 26 from the EUV light generation processor 24 is connected to the delay circuit 26. The output of the delay circuit 26 is input to the laser device 90 as a light emission trigger signal Tr. The output of the delay circuit 26 is input to the EUV energy sensor 52 as a gate signal GS1 for measurement.

The EUV energy sensor 52 detects desired EUV pulse light in accordance with the gate signal GS1. The EUV energy measurement value measured by the EUV energy sensor 52 is transmitted to the EUV light generation processor 24.

The laser device 90 outputs pulse laser light based on the light emission trigger signal Tr. The laser device 90 may be, for example, a CO₂ laser device. Further, the laser device 90 may be a solid-state laser device in which a crystal obtained by doping any one of YVO₄ (yttrium-vanadium oxide), YLF (yttrium-lithium fluoride), and YAG (yttrium-aluminum-garnet) with an impurity is used as a laser medium. The laser light concentrating optical system 54 is an optical system that concentrates the pulse laser light introduced into the chamber 22 on the plasma generation region 80. The laser light concentrating optical system 54 is supported by the XY-axis stage 55. The XY-axis stage 55 can move the laser light concentrating optical system 54 in two axial directions being the X-axis direction and the Y-axis direction. By adjusting the position of the laser light concentrating optical system 54 by the XY-axis stage 55, it is possible to adjust the concentration position of the pulse laser light. Each optical element is arranged such that the concentration position of the laser light concentrating optical system 54 substantially coincides with the plasma generation region 80.

The target collection unit 56 is arranged on the trajectory of the droplet 82, and collects the droplets 82 which have not been irradiated with the pulse laser light.

Further, an EUV light concentrating mirror (not shown) is arranged in the chamber 22. The EUV light concentrating mirror has a spheroidal reflection surface. A multilayer reflective film in which molybdenum and silicon are alternately laminated is formed on the reflection surface of the EUV light concentrating mirror. The EUV light concentrating mirror has a first focal point and a second focal point and is positioned such that the first focal point is located in the plasma generation region 80. The EUV light concentrating mirror selectively reflects EUV light from among the radiation light that is radiated from the plasma generated at the plasma generation region 80. The EUV light concentrating mirror concentrates the selectively reflected EUV light on the second focal point (intermediate focal point). An aperture (not shown) is arranged at the intermediate focal point, and the EUV light having passed through the aperture enters an exposure apparatus or an inspection apparatus (not shown).

### 2.2 Operation

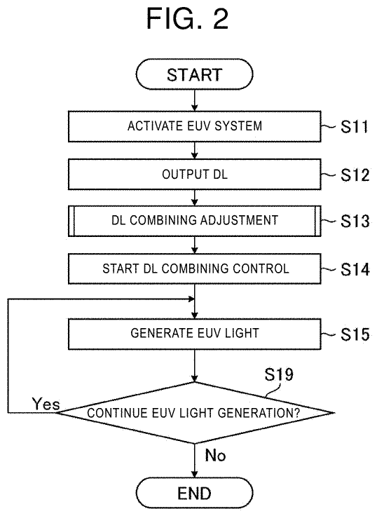

FIG. 2 is a flowchart showing operation of the EUV light generation system 10. In step S11, when the EUV light generation system 10 is activated, a target generation signal is input from the EUV light generation processor 24 to the target generation processor 36.

In step S12, the target generation processor 36 controls the heater power source 38 based on a detection value of the temperature sensor 46 so that the temperature of Sn in the target supply unit 32 is equal to or higher than the melting point, for example, a predetermined temperature of 232° C. to 300° C., and melts Sn stored in the tank 44. The target generation processor 36 also controls the inert gas to a predetermined pressure by the pressure regulator 48, for example, the pressure of 0.2 MPa to 40 MPa, to output the liquid Sn inside the tank 44 to the outside of the nozzle 42.

In step S13, the target generation processor 36 inputs an electric signal of a rectangular wave having a predetermined frequency and a predetermined duty (Duty) to the piezoelectric element 47 via the piezoelectric power source 37 so that the liquid Sn output from the nozzle 42 is turned into droplets and that a plurality of droplets are combined to generate a combining droplet having a predetermined diameter and a predetermined cycle, and the nozzle 42 is vibrated at a predetermined vibration frequency. Hereinafter, the term “droplet” in the case of generating a droplet or generation of a droplet in the present specification refers to a combining droplet unless otherwise specified. Further, in the present specification, the duty of the electric signal of the rectangular wave applied to the piezoelectric element 47 is referred to as the “duty of the piezoelectric element 47” or simply the “duty.” The duty is one of the parameters for controlling the combining state of the droplets, and the value of the duty set to drive the piezoelectric element 47 is referred to as a “duty value.”

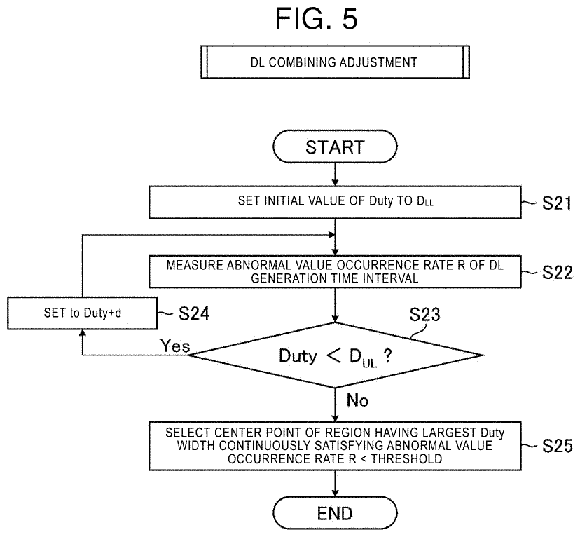

In the step of droplet combining adjustment in step S13, for example, the duty is changed from 1% to 99% by a predetermined step amount (e.g., by 0.1%), an abnormal value occurrence rate of a generation time interval of the droplets 82 at each duty value is measured, and the duty value of the center value of the region having the widest range (duty width) of continuous duty values in which the abnormal value occurrence rate is less than a threshold value is adopted. The generation time interval of the droplets 82 refers to a time interval at which combining droplets are generated, and is hereinafter referred to as a “DL generation time interval.” The DL generation time interval can be grasped from the passage timing signal TS. The target generation processor 36 may acquire information of the DL generation time interval from the EUV light generation processor 24, or may acquire the passage timing signal TS from the light receiving unit 62 of the droplet detection device 50 or via the EUV light generation processor 24. A specific example of a subroutine applied to the process of the droplet combining adjustment in step S13 will be described later with reference to FIG. 5.

In step S14, the EUV light generation processor 24 starts the control of maintaining the combining state of the droplets 82 by controlling the duty of the piezoelectric element 47 using the abnormal value occurrence rate of the DL generation time interval as a control amount. The abnormal value occurrence rate of the DL generation time interval can be defined as a percentage of a value obtained by dividing the number of events of the DL generation time interval distributed outside the allowable range by the number of samples. That is, when NE represents the number of events of the DL generation time intervals distributed outside the allowable range and n represents the number of samples, the abnormal value occurrence rate R is expressed by the following equation.

R=(NE/n)*100[%]

In step S15, the EUV light generation processor 24 inputs the light emission trigger signal Tr to which a set delay time is added to the laser device 90. The pulse laser light output from the laser device 90 in synchronization with the light emission trigger signal Tr reaches the position of the plasma generation region 80 via the laser light concentrating optical system 54. The EUV light is generated by the droplet 82 being irradiated with the pulse laser light.

Thereafter, in S19, the EUV light generation processor 24 determines whether or not to continue the EUV light generation. When the determination result in step S19 is Yes, the EUV light generation processor 24 returns to S15 and continues the EUV light generation. When the determination result in step S19 is No, the EUV light generation processor 24 ends the EUV light generation, and ends the flowchart of FIG. 2.

### 2.3 Problem

As described above, in the EUV light generation system 10 according to the comparative example, the duty of the piezoelectric element 47 is controlled based on the DL generation time interval. However, even when the DL generation time interval is normal, there may be a case in which the droplet 82 having a combining failure in a state with the droplet diameter being smaller than a specific diameter is generated. By irradiating the droplet 82 having such a combining failure with the pulse laser light, the stability of the EUV energy is deteriorated and the amount of debris is increased.

### 3. FIRST EMBODIMENT

### 3.1 Configuration

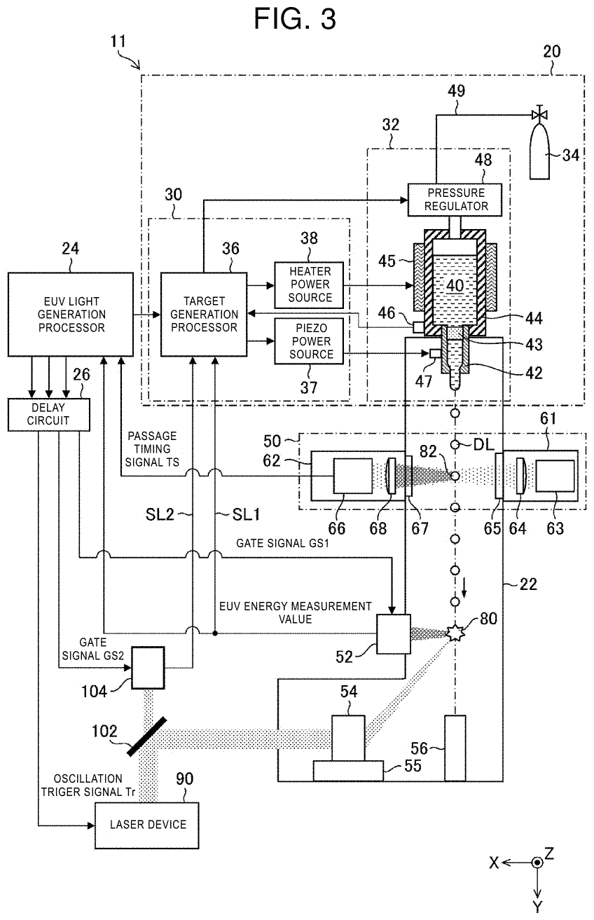

FIG. 3 schematically shows the configuration of the EUV light generation system 11 according to a first embodiment. The configuration shown in FIG. 3 will be described in terms of differences from the configuration shown in FIG. 1. In the EUV light generation system 11, a signal line SL1 is connected to the target generation processor 36 to notify the EUV energy measurement value from the EUV energy sensor 52. The EUV light generation system 11 also includes a beam splitter 102 and a laser energy sensor 104 in addition to the configuration shown in FIG. 1.

The beam splitter 102 is arranged on the optical path of the laser light between the laser device 90 and the laser light concentrating optical system 54. The beam splitter 102 is configured to transmit a part of the incident laser light and reflect another part thereof.

The laser energy sensor 104 is arranged at a position where it receives light having passed through or reflected by the beam splitter 102. Here, the laser energy sensor 104 exemplified in FIG. 3 is arranged at a position where it receives light having passed through the beam splitter 102. An optical system (not shown) may be arranged between the beam splitter 102 and the laser energy sensor 104. The optical system may be a collimating optical system or a light concentrating optical system.

The output of the delay circuit 26 is input to the laser energy sensor 104 as a gate signal GS2 for measurement. A signal line SL2 is connected to the target generation processor 36 to notify the laser energy measurement value from the laser energy sensor 104.

### 3.2 Operation

The laser energy sensor 104 measures the pulse energy of the pulse laser light in accordance with the gate signal GS2. The laser energy measurement value measured by the laser energy sensor 104 and the EUV energy measurement value measured by the EUV energy sensor 52 are transmitted to the target generation processor 36.

The target generation processor 36 calculates the energy conversion efficiency (CE) based on the laser energy measurement value and the EUV energy measurement value. The CE is the conversion efficiency of the EUV energy to driver laser energy and is calculated by the following equation.

CE=(EUV energy/driver laser energy)*100[%]

In the case of the present embodiment, the driver laser energy is the energy of the pulse laser light output from the laser device 90.

During the EUV light generation, the target generation processor 36 controls the combining state of the droplets 82 by controlling the duty of the piezoelectric element 47 using an EUV performance evaluation value such as the CE as the control amount. The EUV energy sensor 52 is an example of the “first sensor” in the present disclosure. The laser energy sensor 104 is an example of the “second sensor” in the present disclosure. The EUV energy measurement value is an example of the “output of the first sensor” in the present disclosure. The laser energy measurement value is an example of the “output of the second sensor” in the present disclosure. The target generation processor 36 or the combination of the EUV light generation processor 24 and the target generation processor 36 is an example of the “processor” in the present disclosure.

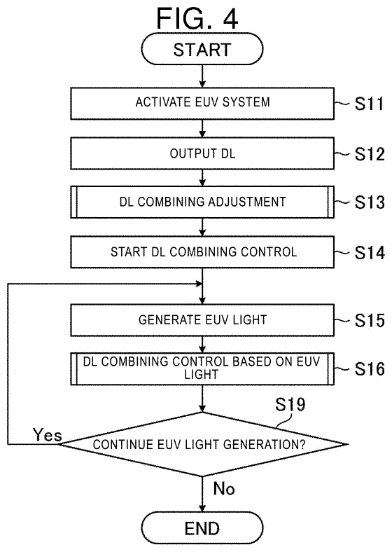

FIG. 4 is a flowchart showing operation of the EUV light generation system 11 according to the first embodiment. In FIG. 4, steps common to FIG. 2 are denoted by the same step numbers. In the flowchart shown in FIG. 4, step S16 is added between step S15 and step S19 of the flowchart of FIG. 2.

That is, after step S15, the target generation processor 36 performs a process of droplet combining control based on the EUV light in step S16. After step S16, processing proceeds to step S19. Other steps may be similar to those in the flowchart of FIG. 2.

### 3.3 Example of Droplet Combining Adjustment

FIG. 5 is a flowchart showing an example of a subroutine applied to step S13 in FIGS. 2 and 4.

When the process of droplet combining adjustment in step S13 is started, in step S21, the target generation processor 36 sets the value of duty (Duty) of the piezoelectric element 47 to an initial value D_{LL}. The duty can be changed in steps of a step amount d in a numerical range from the lower limit value D_{LL} to an upper limit value D_{UL}. As a typical parameter value of the duty, for example, the lower limit value D_{LL} may be 1%, the upper limit value D_{UL} may be 99%, and the step amount d may be 0.1%.

In step S22, the target generation processor 36 measures the abnormal value occurrence rate R of the DL generation time interval. That is, the target generation processor 36 controls the piezoelectric power source 37 so as to apply the electric signal of a rectangular wave of the set duty value to the piezoelectric element 47, generates the droplets 82 by driving the piezoelectric element 47 via the piezoelectric power source 37, and measures the abnormal value occurrence rate R of the DL generation time interval. The target generation processor 36 stores the measured abnormal value occurrence rate R in association with the duty value.

In step S23, the target generation processor 36 determines whether or not the set value of the duty is less than the upper limit value D_{UL}. When the determination result in step S23 is Yes, the target generation processor 36 proceeds to S24, updates the set value of the duty by adding the step amount d to the set value of the duty, and then returns to step S22.

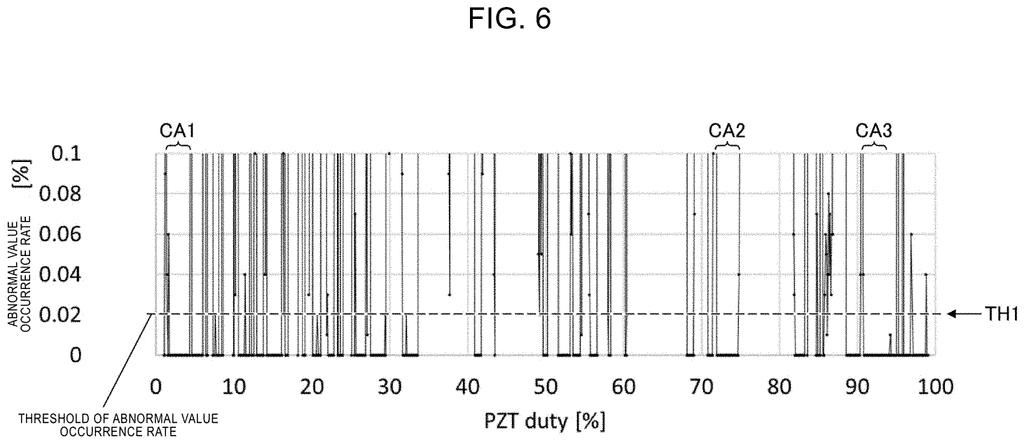

The loop of steps S22 to S24 is repeated until the set value of the duty reaches the upper limit value D_{UL}. Thus, by measuring the abnormal value occurrence rate R of the DL generation time interval at each duty value while increasing the duty from the lower limit value D_{LL} to the upper limit value D_{UL} by the step amount d, characteristic data (see FIG. 6) indicating the relationship between the duty value and the abnormal value occurrence rate R of the DL generation time interval is obtained.

When the determination result in step S23 is No, the target generation processor 36 proceeds to step S25. In step S25, the target generation processor 36 sets a region (duty range) in which a continuous duty width in which the abnormal value occurrence rate R is less than the threshold TH1 is equal to or more than a specific width as a usable region candidate, and selects the duty value that is the center point of a region having the largest duty width among the usable region candidates (duty width maximum region).

After step S25, the target generation processor 36 returns to the flowchart of FIG. 2 or FIG. 4.

FIG. 6 is a graph showing an example of the abnormal value occurrence rate R of the DL generation time interval measured in the droplet combining adjustment. The horizontal axis represents the duty, and the vertical axis represents the abnormal value occurrence rate R. FIG. 6 is an example of a graph of the abnormal value occurrence rate R of the DL generation time interval obtained by scanning the duty from 1% to 99% by increments of 0.1% while the irradiation of the pulse laser light is stopped.

FIG. 6 shows an example in which the threshold TH1 of the abnormal value occurrence rate R is set to 0.02%. In FIG. 6, the usable region candidates satisfying the condition that the continuous duty width in which the abnormal value occurrence rate R is less than the threshold TH1 is equal to or more than the specific width are three regions, that is, a region candidate CA1 at which the duty value is near 3%, a region candidate CA2 at which the duty value is near 72%, and a region candidate CA3 at which the duty value is near 92%. Among these region candidates, the region having the largest duty width (here, the region candidate CA3) is selected as the duty width maximum region, and the duty value of the center of the duty range of the region candidate CA3 is selected as the duty value suitable for generating the droplet 82. The droplet detection device 50 used for detecting the DL generation time interval is an example of the “third sensor” in the present disclosure. Each of the region candidates CA1 to CA3 is an example of the “range of duty values in which the generation time interval of the droplet is normal” in the present disclosure.

### 3.4 Example of Droplet Combining Control Based on EUV Light

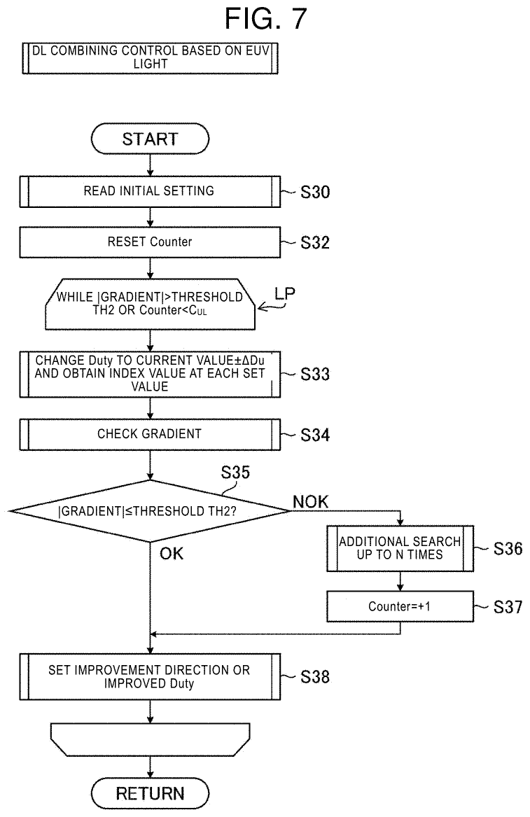

FIG. 7 is a flowchart showing an example of a subroutine applied to step S16 in FIG. 4. When the process of droplet combining control based on the EUV light in step S16 is started, in step S30, the target generation processor 36 reads the initial setting. Parameters for performing the initial setting include, for example, a threshold TH2 of the gradient of an index value for evaluating EUV performance, a search width ΔDu for searching for the value of the duty, a minute amount dm of the duty, an upper limit value C_{UL} of a counter, and a number of additional search N. The target generation processor 36 reads the initial setting value for each of these parameters. The minute amount dm is set to an appropriate value satisfying the condition of 0<dm≤ΔDu. For example, dm=ΔDu/2 may be satisfied.

In step S32, the target generation processor 36 resets the counter.

After step S32, the target generation processor 36 proceeds to a loop process LP. The loop process LP includes steps S33 to S38. In the loop process LP, when the gradient of the index value is equal to or less than the threshold TH2, the target generation processor 36 performs fine adjustment to change the duty value by a small amount dm in an improvement direction, and ends the loop process LP. When the gradient of the index value exceeds the threshold TH2, the target generation processor 36 repeats the loop process LP until the gradient is equal to or less than the threshold TH2, and continues to adjust (search) the duty. The target generation processor 36 also monitors the value of the counter that counts the number of times the loop process LP is executed to avoid an infinite loop. In place of the counter, a timer may be used to monitor the time. When the value of the counter reaches the upper limit value C_{UL}, the target generation processor 36 ends the loop process LP.

In step S33, the target generation processor 36 changes the setting of the duty from the current value to the current value±ΔDu, and acquires the index value at each duty value of “current value”, “current value−ΔDu”, and “current value+ΔDu.” The index used for the evaluation of the CE may be, for example, 3σ of the CE, 3σ of the CE difference, the abnormal value generation rate of the CE, or the abnormal value occurrence rate of the CE difference. Here, σ represents the standard deviation.

The CE difference is a difference in CE between two consecutive pulses, and a CE difference dCE(k) is defined by the following equation, where k is an integer representing a pulse number.

dCE(k)=CE(k)−CE(k−1)

Here, CE(k) represents the CE of the pulse number k.

The abnormal value occurrence rate of the CE or that of the CE difference refers to a data occurrence rate outside the allowable range (normal range), and can be defined as a percentage of a value obtained by dividing the number of events of the CE or the CE difference distributed outside the allowable range by the number of samples n. The number of samples n for obtaining the index value may be, for example, 20000 pulses.

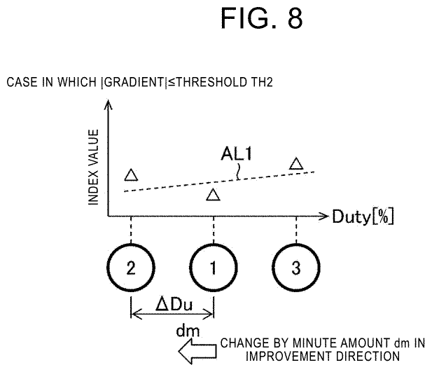

Next, in step S34, the target generation processor 36 checks the gradient of the index value. The gradient may be the slope of a linear approximation of the index values at the three points (see FIG. 8).

In step S35, the target generation processor 36 determines whether or not the condition that the absolute value of the gradient is equal to or less than the threshold TH2 is satisfied.

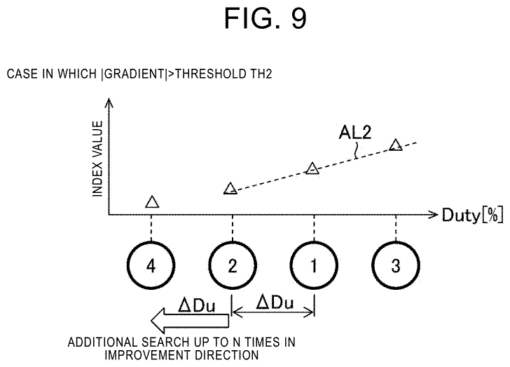

When the determination result in step S35 is OK, the target generation processor 36 proceeds to step S38. When the determination result in step S35 is NOK (Not OK), the target generation processor 36 proceeds to step S36. In step S36, the target generation processor 36 performs additional search up to N times in the improvement direction grasped from the gradient (see FIG. 9). The duty change amount at the time of the additional search may be the search width ΔDu.

After step S36, the target generation processor 36 proceeds to step S37, increments the value of the counter to update the value of the counter, and proceeds to step S38. That is, when the gradient indicating the ratio of the change in the index value of the index to the change in the duty value is larger than the threshold TH2 in the determination in S35, the target generation processor 36 changes the duty value in the direction in which the index value tends to improve (improvement direction), acquires the index value at an additional fourth point, and obtains the gradient at the three neighboring points. Thereafter, the index value is acquired by additional search up to N times until the gradient becomes equal to or less than the threshold TH2.

In S38, when the gradient becomes equal to or less than the threshold TH2, the target generation processor 36 sets the duty to a value obtained by changing the duty from the center of the duty values at the three points used for calculating the gradient to a value obtained by changing the duty by a small amount dm in the improvement direction. At this time, when dm=ΔDu is satisfied, the duty value having the smallest index value is set among the duty values at the three points used for calculating the gradient.

When the termination condition of the loop process LP is satisfied, the target generation processor 36 ends the flowchart of FIG. 7, and returns to the flowchart of FIG. 4.

FIG. 8 is an explanatory diagram of a process of checking the gradient and changing the duty value to improve the index value. FIG. 8 shows an example in which the absolute value of the gradient is equal to or less than the threshold TH2. The horizontal axis represents the duty, and the vertical axis represents the index value. The circles in FIG. 8 indicate the duty set values, and the numbers in the circles indicate the setting order. For example, the setting order 1 corresponds to “current value”, the setting order 2 corresponds to “current value−ΔDu”, and the setting order 3 corresponds to “current value+ΔDu.” From these three points, the slope (gradient) of an approximate straight line AL1 indicated by a broken line can be obtained by linear approximation. The gradient of the index value is preferably defined on the basis of data of at least three points.

In the example of FIG. 8, the slope of the approximate straight line AL1 is positive, and the direction of decreasing the duty value with respect to the “current value” of the duty is the direction of improving the index value. Therefore, in this case, as the process of step S38, the duty value is changed from the current value in the minus direction (improvement direction) by the minute amount dm.

FIG. 9 is an explanatory diagram showing an example of the process of an additional search performed when the absolute value of the gradient is larger than the threshold TH2. The description rule of FIG. 9 is similar to that of FIG. 8. In the example of FIG. 9, the slope of the approximate straight line AL2 obtained from the index values at the three points is positive, and the absolute value of the gradient is larger than the threshold TH2. The direction of decreasing the value of Duty is the direction of improving the index value, and the additional search is performed by changing the duty value by ΔDu in the minus direction from the Duty set value at the setting order 2. The duty value of the setting order 4 is set by the additional search. Then, the gradient of the index value is redefined from the three neighboring points including the added point. Such an additional search in the improvement direction may be performed up to N times.

### 3.5 Example of Evaluation Method of CE

As described in detail with reference to FIGS. 8 and 9, in the EUV light generation system 11 according to the first embodiment, the variation of the CE calculated based on the output of the EUV energy sensor 52 and the output of the laser energy sensor 104 is evaluated, and the duty value of the piezoelectric element 47 is controlled so as to decrease the variation based on the evaluation value (index value) of the variation. Evaluating the variation of the CE corresponds to evaluating the stability of the energy of the generated EUV light, that is, evaluating the performance of EUV light generation.

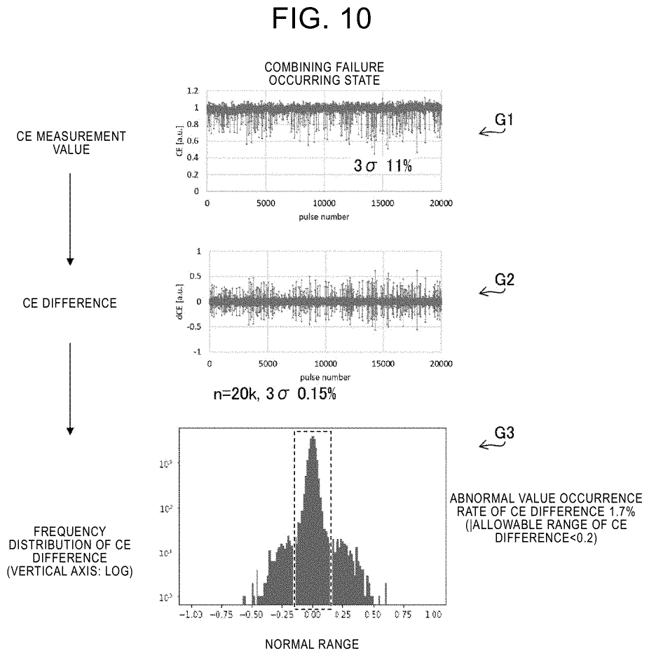

FIG. 10 is a graph showing an example of the CE measurement value, the CE difference, and a frequency distribution of the CE difference in a case that the combining failure of the droplets 82 is occurring. In a graph G1 shown in the upper part of FIG. 10, the horizontal axis represents the pulse number and the vertical axis represents the CE measurement value in an arbitrary unit. In a graph G2 shown in the middle part of FIG. 10, the horizontal axis represents the pulse number and the vertical axis represents the CE difference in an arbitrary unit. A graph G3 shown in the lower part of FIG. 10 is a frequency distribution (histogram) of the CE difference. The vertical axis of the graph G3 is expressed in logarithmic (LOG) representation.

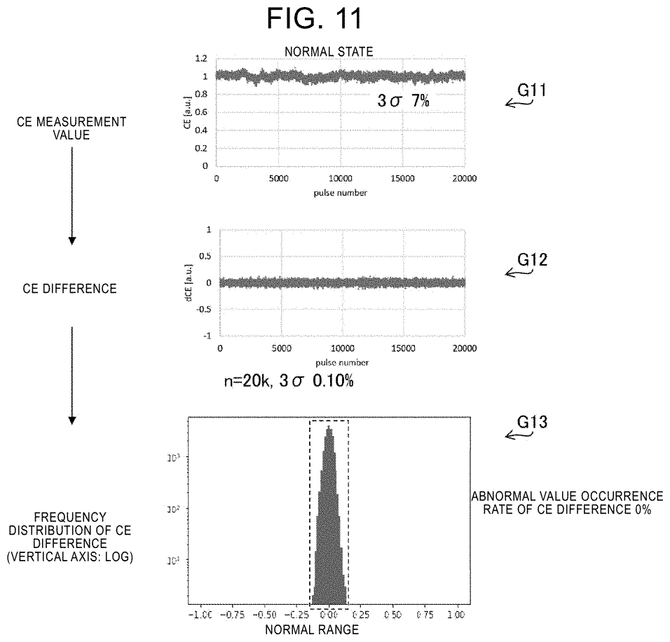

Further, FIG. 11 is a graph showing an example of the CE measurement value, the CE difference, and the frequency distribution of the CE difference in a case that the combining of the droplets 82 is normal. A graph G11 shown in the upper part of FIG. 11 shows the CE measurement value, a graph G12 shown in the middle part shows the CE difference, and a graph G13 shown in the lower part shows the frequency distribution of the CE difference. The horizontal axis and the vertical axis of each graph are similar to those of the corresponding graph in FIG. 10.

As is apparent from a comparison between FIGS. 10 and 11, when a combining failure occurs, variations of the CE measurement value and the CE difference measured in pulse order are larger than those in the normal state. In the example of FIG. 11, 3σ of the CE measurement value in the normal state is 7%. On the other hand, in the example of FIG. 10, 3σ of the CE measurement value at the time of occurrence of the combining failure is 11%. Further, 3σ of the CE difference in the normal state shown in the example of FIG. 11 is 0.1%, whereas 3σ of the CE difference at the time of occurrence of combining failure shown in the example of FIG. 10 is 0.15%.

As shown in the lower parts of FIGS. 10 and 11, for example, when a range in which the absolute value of the CE difference is less than 0.2 (−0.2<dCE<−0.2) is set as the allowable range (normal range) of the CE difference, the abnormal value occurrence rate of the CE difference at the normal time shown in the example of FIG. 11 is 0%, whereas the abnormal value occurrence rate of the CE difference at the time of occurrence of the combining failure shown in the example of FIG. 10 is 1.7%.

Thus, by controlling the duty of the piezoelectric element 47 using an index for evaluating the variation of the CE, such as 3σ of the CE measurement value reflecting the DL combining state, 3σ of the CE difference, or the abnormal value occurrence rate of the CE difference, it is possible to suppress the occurrence of the DL combining failure state which is difficult to be detected from the abnormal value occurrence rate R of the DL generation time interval. The DL combining failure state in which detection is difficult from the abnormal value occurrence rate R of the DL generation time interval includes a combining failure state in which the droplet diameter is decreased while the DL generation time interval is maintained within an allowable range.

### 3.6 Effect

In the EUV light generation system 11 according to the first embodiment, the duty of the piezoelectric element 47 is controlled by using the EUV performance evaluation value such as the CE in the pulse order (every pulse) which is a direct index of the EUV light. According to this, it is possible to avoid the DL combining failure state that cannot be detected from the abnormal value occurrence rate R of the DL generation time interval. By avoiding such a DL combining failure state, improvement of the energy stability of the EUV light and debris reduction can be expected.

### 4. SECOND EMBODIMENT

### 4.1 Configuration

The configuration of the EUV light generation system 11 according to a second embodiment may be similar to that shown in FIG. 3.

### 4.2 Operation

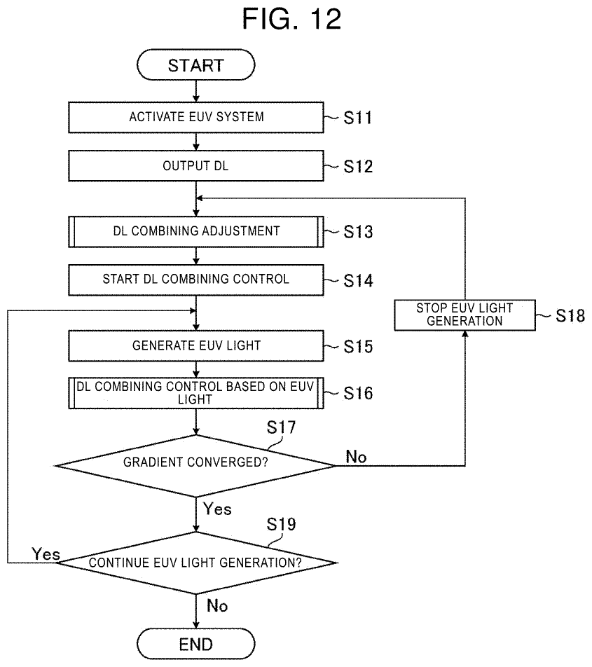

FIG. 12 is a flowchart showing an example of operation of the EUV light generation system 11 according to the second embodiment. In the second embodiment, the flowchart of FIG. 12 is applied instead of the flowchart of FIG. 4.

The flowchart shown in FIG. 12 will be described in terms of differences from that shown in FIG. 4. In the flowchart of FIG. 12, step S17 and step S18 are added between step S16 and step S19 of FIG. 4. That is, after step S16, the target generation processor 36 proceeds to step S17. In step S17, the target generation processor 36 determines whether or not the gradient of the index value is converged. When the gradient determined in the subroutine of the DL combining control based on the EUV light described in FIG. 7 is not converged and the value of the counter reaches the upper limit value C_{UL} and thus the loop process LP is exited, the determination result in step S17 is No.

When the determination result in step S17 is No, the target generation processor 36 proceeds to S18 and the EUV light generation is stopped. After step S18, the target generation processor 36 returns to step S13.

When the determination result in step S17 is Yes, the target generation processor 36 proceeds to step S19.

The processes of the other steps are similar to those in the flowchart of FIG. 4.

### 4.3 Effect

In the second embodiment, when the DL combining state is not improved by the DL combining control based on the EUV light in step S16 (step S17: No), the EUV light generation is stopped (step S18) and processing returns to the DL combining adjustment (step S13). According to this, even when the value of the duty suitable for generating the droplet 82 changes significantly, the DL combining adjustment (step S13) is performed again, and thus it is possible to re-derive the duty that enables the DL combining with less combining failure. As a result, it is possible to return to a stable EUV light generation operation state. Also in the EUV light generation system 11 according to the second embodiment, similarly to the first embodiment, the DL combining failure state that cannot be detected from the abnormal value occurrence rate R of the DL generation time interval can be avoided, and improvement of the EUV energy stability and debris reduction can be expected.

### 5. THIRD EMBODIMENT

### 5.1 Configuration

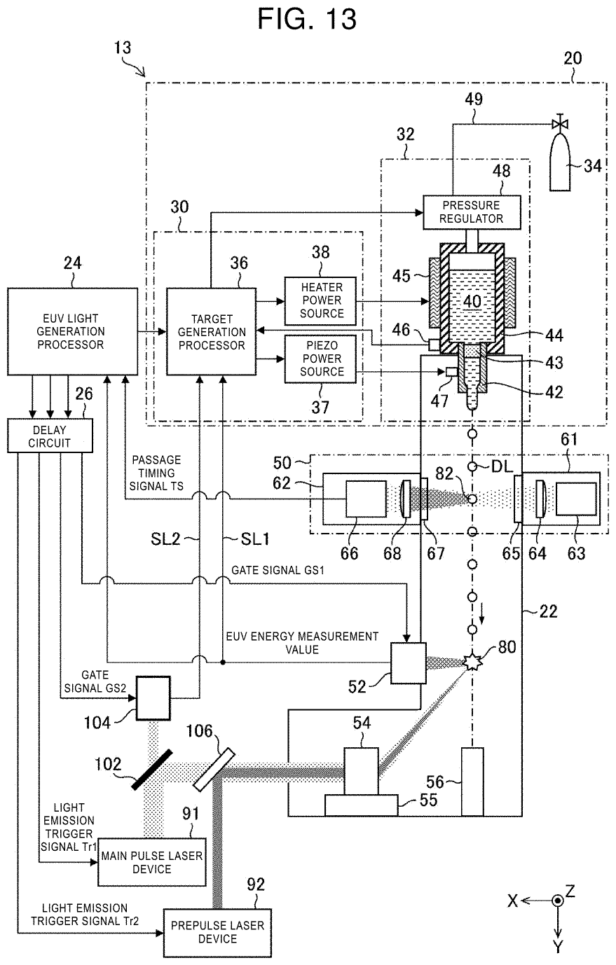

FIG. 13 schematically shows the configuration of an EUV light generation system 13 according to a third embodiment. The configuration shown in FIG. 13 will be described in terms of differences from the configuration shown in FIG. 3. The EUV light generation system 13 shown in FIG. 13 includes a main pulse laser device 91 as the laser device 90 of FIG. 3, and further includes a prepulse laser device 92. Further, a beam combiner 106 is provided on the optical path between the beam splitter 102 and the laser light concentrating optical system 54. Other configurations may be similar to those in FIG. 3.

The prepulse laser device 92 may be a laser device that outputs prepulse laser light having a pulse width of a picosecond order (less than 1 ns), or may be a laser device that outputs prepulse laser light having a pulse width of a nanosecond order. The prepulse laser device 92 may be, for example, an Nd:YAG laser of a solid-state laser device that outputs harmonic light thereof, or a gas laser device such as a CO₂ laser or an excimer laser.

The beam combiner 106 is an optical element that reflects light including a wavelength component of the prepulse laser light at high reflectance and transmits light including a wavelength component of the main pulse laser light at high transmittance, and may be, for example, a dichroic mirror. The prepulse laser light reflected by the beam combiner 106 and the main pulse laser beam transmitted through the beam combiner 106 reaches the position of the plasma generation region 80. Alternatively, the beam combiner 106 may be an optical element that reflects light including the wavelength component of the main pulse laser light at high reflectance and transmits light including the wavelength component of the prepulse laser light at high transmittance. However, in such a case, the main pulse laser device is arranged upstream of the optical path of the laser light to be reflected, and the prepulse laser device is arranged upstream of the optical path of the laser light to be transmitted. The beam splitter 102 is arranged on the optical path of the main pulse laser light between the main pulse laser device and the beam combiner 106. Also with this arrangement, the prepulse laser light and the main pulse laser light reach the position of the plasma generation region 80.

### 5.2 Operation

The EUV light generation processor 24 calculates a delay time for the prepulse laser device 92 and a delay time for the main pulse laser device 91 based on the passage timing signal TS, and sets the delay times in the delay circuit 26. At this time, the delay time for the prepulse laser device 92 is set to be shorter.

The delay circuit 26 outputs a light emission trigger signal Tr2 obtained by adding the delay time for the prepulse laser device 92 to the prepulse laser device 92, and outputs a light emission trigger signal Tr1 obtained by adding the delay time for the main pulse laser device 91 to the main pulse laser device 91.

The prepulse laser device 92 outputs the prepulse laser light in accordance with the light emission trigger signal Tr2. The main pulse laser device 91 outputs main pulse laser light in accordance with the light emission trigger signal Tr1. At this time, since the delay time for the prepulse laser device 92 is set to be shorter, the prepulse laser light and the main pulse laser light is output in this order.

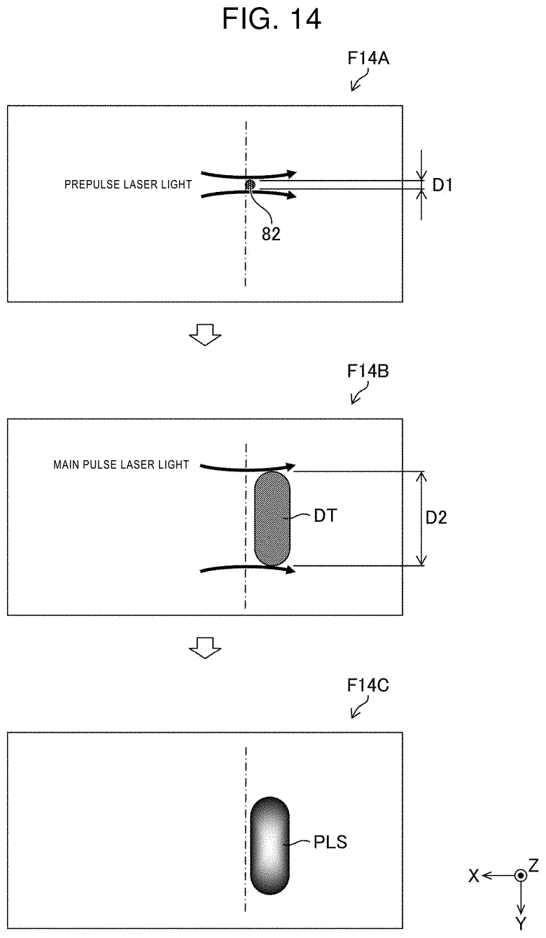

FIG. 14 is an explanatory diagram schematically showing the state of the EUV light generation by a secondary target. A state F14A shown in the upper part of FIG. 14 shows a state of irradiating the droplet 82 with the prepulse laser light. A state F14B shown in the middle part of FIG. 14 shows a state of irradiating a diffusion target DT which is the secondary target with the main pulse laser light. A state F14C shown in the lower part of FIG. 14 shows a state of plasma PLS generated by the irradiation of the main pulse laser light.

As shown in the upper part of FIG. 14, when the droplet 82 having a diameter D1 is irradiated with the prepulse laser light (F14A), the droplet 82 is broken and diffused into a plurality of fine particles, and the diffusion target DT having a diameter D2 larger than the diameter D1 is generated (F14B). By irradiating the diffusion target DT with the main pulse laser light, the target substance 40 is efficiently turned into plasma, and the EUV light is generated. The control method of the combining state of the droplets 82 may be similar to that in the first embodiment or the second embodiment.

### 5.3 Effect

The EUV light generation system 13 according to the third embodiment can generate the EUV light more efficiently than the EUV light generation system 11 according to the first embodiment or the second embodiment. Also in the EUV light generation system 13 according to the third embodiment, similarly to the first embodiment or the second embodiment, the DL combining failure state that cannot be detected from the abnormal value occurrence rate R of the DL generation time interval can be avoided, and improvement of the EUV energy stability and debris reduction can be expected.

### 6. ELECTRONIC DEVICE MANUFACTURING METHOD

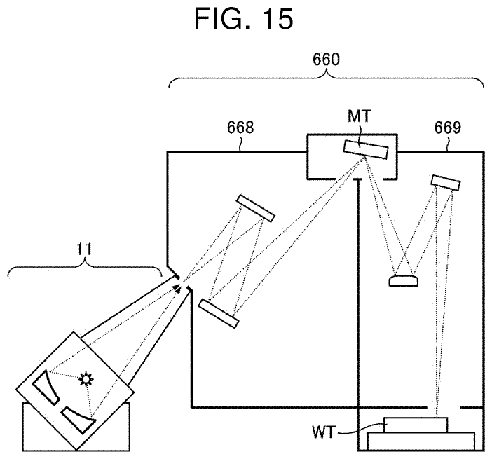

FIG. 15 schematically shows the configuration of an exposure apparatus 660 connected to the EUV light generation system 11. The exposure apparatus 660 includes a mask irradiation unit 668 and a workpiece irradiation unit 669. The mask irradiation unit 668 illuminates, via a reflection optical system, a reticle pattern of a reticle table MT with EUV light incident from the EUV light generation system 11. The workpiece irradiation unit 669 images the EUV light reflected by the reticle table MT onto a workpiece (not shown) placed on the workpiece table WT through a reflection optical system. The workpiece is a photosensitive substrate such as a semiconductor wafer on which photoresist is applied.

The exposure apparatus 660 synchronously translates the reticle table MT and the workpiece table WT to expose the workpiece to the EUV light reflecting the reticle pattern. Through the exposure process as described above, a device pattern is transferred onto the semiconductor wafer, thereby an electronic device can be manufactured. The EUV light generation system 13 may be used instead of the EUV light generation system 11.

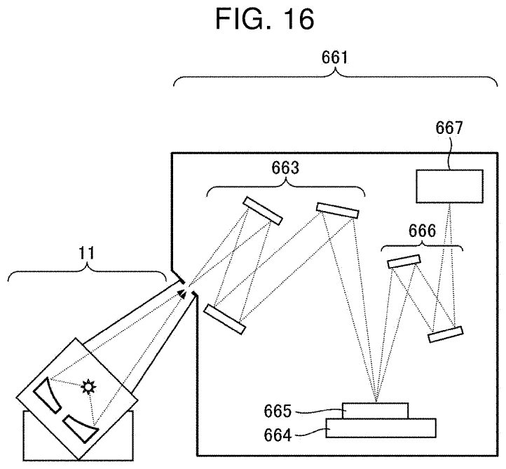

FIG. 16 schematically shows the configuration of an inspection apparatus 661 connected to the EUV light generation system 11. The inspection apparatus 661 includes an illumination optical system 663 and a detection optical system 666. The illumination optical system 663 reflects the EUV light incident from the EUV light generation system 11 to illuminate a reticle 665 placed on a reticle stage 664. Here, the reticle 665 conceptually includes a mask blanks before a pattern is formed. The detection optical system 666 reflects the EUV light from the illuminated reticle 665 and forms an image on a light receiving surface of a detector 667. The detector 667 having received the EUV light obtains the image of the reticle 665. The detector 667 is, for example, a time delay integration (TDI) camera.

Defects of the reticle 665 are inspected based on the image of the reticle 665 obtained by the above-described process, and a reticle suitable for manufacturing an electronic device is selected using the inspection result. Then, the electronic device can be manufactured by exposing and transferring the pattern formed on the selected reticle onto the photosensitive substrate using the exposure apparatus 660. In the configuration shown in FIG. 16 as well, the EUV light generation system 13 may be used instead of the EUV light generation system 11.

### 7. OTHERS

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. An extreme ultraviolet light generation system configured to generate extreme ultraviolet light by irradiating a target substance with laser light, comprising:
a nozzle configured to output the target substance;
a vibration element that is driven by an input of an electric signal of a rectangular wave and applies vibration to the target substance to be output from the nozzle to generate droplets of the target substance;
a first sensor configured to detect energy of the generated extreme ultraviolet light;
a second sensor configured to detect energy of the laser light to be radiated to the target substance; and
a processor configured to control a duty value of the electric signal for vibrating the vibration element so as to reduce a variation of an energy conversion efficiency calculated based on an output of the first sensor and an output of the second sensor.

2. The extreme ultraviolet light generation system according to claim 1,
wherein the energy conversion efficiency is represented by a value obtained by dividing the energy of the extreme ultraviolet light by the energy of the laser light.

3. The extreme ultraviolet light generation system according to claim 2,
wherein the variation in the energy conversion efficiency is evaluated using, as an index, any one of three times a standard deviation of the energy conversion efficiency, three times a standard deviation of a difference in the energy conversion efficiency, and an abnormal value occurrence rate of the difference in the energy conversion efficiency.

4. The extreme ultraviolet light generation system according to claim 3,
wherein a difference DCe(k) in the energy conversion efficiency is represented by DCe(k)=CE(k)−CE(k−1), where k is an integer representing a pulse number of the generated extreme ultraviolet light and CE(k) is an energy conversion efficiency of the pulse number k.

5. The extreme ultraviolet light generation system according to claim 4,
wherein the abnormal value occurrence rate of the energy conversion efficiency is represented by a percentage of a value obtained by dividing a number of events of the difference of the energy conversion efficiency distributed outside an allowable range by a number of samples.

6. The extreme ultraviolet light generation system according to claim 1,
wherein the duty value is controlled based on a gradient of an index of the variation.

7. The extreme ultraviolet light generation system according to claim 6,
wherein the gradient is defined based on a value of the index obtained by defining at least three points of the duty value.

8. The extreme ultraviolet light generation system according to claim 7,
wherein the duty value is controlled so that the value of the index becomes smaller.

9. The extreme ultraviolet light generation system according to claim 6,
wherein, when the absolute value of the gradient exceeds a threshold, the processor performs additional search for acquiring the value of the index by changing the duty value in a direction in which the value of the index decreases, and redefines the gradient using the value of the index acquired by the additional search.

10. The extreme ultraviolet light generation system according to claim 1,
wherein the laser light is pulse laser light, and
the processor measures the energy conversion efficiency for each pulse.

11. The extreme ultraviolet light generation system according to claim 1, further comprising a third sensor configured to detect a generation time interval of the droplets,
wherein the processor controls the generation time interval of the droplets by controlling the duty value based on a detection result of the third sensor.

12. The extreme ultraviolet light generation system according to claim 11,
wherein the processor selects one or more ranges of the duty value in which the generation time interval of the droplets is normal based on an output of the third sensor obtained by scanning the duty value, and selects a center value of a largest range from the one or more selected normal ranges of the duty value.

13. The extreme ultraviolet light generation system according to claim 11,
wherein the processor controls the generation time interval of the droplets based on the detection result of the third sensor in a state in which irradiation of the target substance with the laser light is stopped.

14. The extreme ultraviolet light generation system according to claim 9, further comprising a third sensor configured to detect a generation time interval of the droplets,
wherein, when an absolute value of the gradient exceeds the threshold even after the additional search is performed for a plurality of times, the processor stops generation of the extreme ultraviolet light and controls the generation time interval of the droplets by controlling the duty value based on a detection result of the third sensor.

15. The extreme ultraviolet light generation system according to claim 1,
wherein the target substance in a state of the droplet is irradiated with the laser light.

16. The extreme ultraviolet light generation system according to claim 1,
wherein the target substance in a state in which the droplet is diffused into a plurality of fine particles is irradiated with the laser light.

17. An electronic device manufacturing method, comprising:
generating extreme ultraviolet light using an extreme ultraviolet light generation system;
outputting the extreme ultraviolet light to an exposure apparatus; and
exposing a photosensitive substrate to the extreme ultraviolet light in the exposure apparatus to manufacture an electronic device,
the extreme ultraviolet light generation system including:
a nozzle configured to output a target substance;
a vibration element that is driven by an input of an electric signal of a rectangular wave and applies vibration to the target substance to be output from the nozzle to generate droplets of the target substance;
a first sensor configured to detect energy of the extreme ultraviolet light generated by irradiating the target substance with laser light;
a second sensor configured to detect energy of the laser light to be radiated to the target substance; and
a processor configured to control a duty value of the electric signal for vibrating the vibration element so as to reduce a variation in energy conversion efficiency calculated based on an output of the first sensor and an output of the second sensor.

18. An electronic device manufacturing method, comprising:
generating extreme ultraviolet light using an extreme ultraviolet light generation system;
inspecting a defect of a reticle by irradiating the reticle with the extreme ultraviolet light;
selecting a reticle using a result of the inspection; and
exposing and transferring a pattern formed on the selected reticle onto a photosensitive substrate,
the extreme ultraviolet light generation system including:
a nozzle configured to output a target substance;
a vibration element that is driven by an input of an electric signal of a rectangular wave and applies vibration to the target substance to be output from the nozzle to generate droplets of the target substance;
a first sensor configured to detect energy of the extreme ultraviolet light generated by irradiating the target substance with laser light;
a second sensor configured to detect energy of the laser light to be radiated to the target substance; and
a processor configured to control a duty value of the electric signal for vibrating the vibration element so as to reduce a variation of an energy conversion efficiency calculated based on an output of the first sensor and an output of the second sensor.
